(19) United States
(12) Patent Application Publication
(10) Pub. No.: US 2010/0155910 A1
(43) Pub. Date: Jun. 24, 2010

(54) METHOD FOR THE SELECTIVE ANTIREFLECTION COATING OF A SEMICONDUCTOR INTERFACE BY A PARTICULAR PROCESS IMPLEMENTATION

(75) Inventor: Daniel Gaebler, Ilmenau (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-FAB SEMICONDUCTOR FOUNDRIES AG., Erfurt (DE)

(21) Appl. No.: 12/305,092

(22) PCT Filed: Jun. 16, 2007
(86) PCT No.: PCT/EP2007/055984

§ 371 Date: Oct. 12, 2009

(30) Foreign Application Priority Data
Jun. 17, 2006 (DE) 10 2006 027 969.7

(51) Int. Cl. H01L 31/0216; H01L 31/18; H01L 21/31; H01L 21/302

(52) U.S. Cl. 257/649; 438/72; 438/758; 438/694; 257/E31.119; 257/E21.214; 257/E21.24

(57) ABSTRACT

The invention refers to an efficient process for selectively rendering a semiconductor surface antireflective which is part of integrated circuits. The antireflective effect is based interference effects of a simple layer or a layer system. For example, an oxide layer and super-imposed silicon nitride layer form the system, wherein the silicon nitride layer is deposited in an earlier phase of the fabrication of the integrated circuit as a protective layer (“silicide block layer”) and also serves as an etch stop layer for the optical window.

### CROSS-REFERENCE TO RELATED APPLICATIONS

This application is a U.S. National Stage Application of International Application No. PCT/EP2007/055984, filed Jun. 16, 2007, which claims the benefit of German Patent Application No. DE 10 2006 027 969.7, filed on Jun. 17, 2006, the disclosures of which are herein incorporated by reference in its entirety.

### BACKGROUND OF THE INVENTION

1. Field of the Invention

Antireflective coatings (Anti Reflection Coating ARC) on the basis of interference phenomena are common since the beginning of the 20^{th} century and are frequently used. Single antireflection coatings or basic coating systems are already used also in solar cells and photo diodes.

2. Description of Related Art

For guaranteeing their function, semiconductor circuits are provided with a passivation layer which may, for example, consist out of silicon dioxide or silicon nitride. Both materials can be used as antireflection coating, however, the optical requirements for such coatings do not agree with the requirement of the passivation so that they are applied independently from each other. A circuit is passivated, and, if it is necessary to render it antireflective at optical window areas of the chip, the passivation is removed at these locations up to the silicon surface, and an optimized antireflection coating is applied, see WO-A 2004/021452. An area of a waver which is configured such that it ensures that a specific optical decoupling of the light into the substrate is guaranteed is called optical window.

A disadvantage of this process control is caused by the “late” deposition of the antireflection coating. Since after the complete passivation of a circuit aluminium contact paths are already present, a high temperature deposition is not possible anymore. If, for example, silicon nitride layers are deposited at a low temperature, they contain hydrogen. It reduces the refractive index which has a negative effect on the antireflection properties. Furthermore, it can result in changes in the device by the ultraviolet (UV) exposure, see IEEE 1996 0-7803-2753-5/96. This is contradictory to the required long-time stability of integrated components.

The surface of the semiconductor is influenced in a negative sense by the removal of the passivation layer. Dry etch processes and also wet chemical etch processes produce defects and contaminations in the areas in the vicinity of the surface, see J. Vac, Sci. Technol. A17 (1999) No. 3, pages 749 to 754. Furthermore, such a process step is very complex. In order to remove a thick passivation layer (some μm to over 10 μm) which, without CMP (Chemical Mechanical Polishing), may also still have areas of very much different thickness, a complicated and time consuming etch process is necessary. It may even be necessary to use several etch processes with separate etch stops.

More simple antireflective coating processes can get along without the removal of the complete passivation at the designated areas and are based on a defined deposition on the existing passivation layer. The obtainable antireflective power and quality is, however, very much lower in these processes. Only the border surface of passivation/air can be made antireflective which (border layer), however, has only a small share of the total reflection losses.

The largest reflection losses occur at the border surface silicon/passivation. Therefore, a high quality antireflective coating of integrated circuits tries to minimize this border layer reflection.

### SUMMARY OF THE INVENTION

The invention is based on the object to remove the above mentioned deficiencies of the fabrication of ARC-layers and to improve the quality of the ARC-coating, to simultaneously simplify the fabrication process and to increase yield as well as to reduce the costs.

According to an aspect of the invention, this object is achieved by a method for fabricating an optical semiconductor component having an optical window. Therein, at first a layer stack which is transparent in a defined wavelength range, is formed on a semiconductor area which serves to couple in radiation wherein the transparent layer stack is produced with optical characteristics which are adapted for use as antireflection coating in connection with the optical characteristics of the semiconductor area. Thereafter, one or several metallization levels are formed over the transparent layer stack followed by forming an optical window over the semiconductor area by means of etching of the one or the plurality of metallization levels while using the transparent layer stack as etch stop layer.

By means of the process of the invention, the surface of the semiconductor area upon formation of the optical window remains protected by the edge stop layer which is simultaneously provided with optical characteristics which allow the use as antireflection coating. Thereby, the semiconductor surface can remain to be covered, however, by the layer stack also during the subsequent processing such that the integrity of the semiconductor surface and, thereby, the quantum efficiency for the conversion of the radiation coupled in, is conserved. For example, the defined wavelength area may comprise radiation of a short wavelength for which a high degree of intactness of the semiconductor structure in the area near the surface is very important.

The surface of the semiconductor is of decisive importance for the quantum efficiency in particular for optoelectronic components which operate in the short wave length area (blue). Defects, as they are produced near the surface by etch processes; remarkably reduce the efficiency of the component. Furthermore, defects in the silicon (so-called traps or charge collecting areas) can deteriorate the dynamic properties of the components. By activation and deactivation of traps, undesired changes in the dynamic properties can be encountered. Therefore, an intact or only slightly damaged surface is extremely important.

The complicated etch process for selectively removing the thick and partially inhomogeneous passivation layer can now stop on the ARC-layer and does not reach the sensible silicon surface anymore. A formation of contamination and defects in the silicon areas near to the surface is effectively prevented thereby.

By using a material which is different from the passivation stack, for the ARC-layer it can be used as an etch stop because of different etch rates. Etching of the silicon surface is dispensed with, and, thereby, also the removal of silicon which, otherwise, leads to a deterioration of the conductivity of the introduced diffusion regions.

Finally, the separate deposition of an ARC-layer or an ARC-layer system, respectively, is dispensed with. Thereby, costs and time can be saved. Also the risk of faults of the fabrication is lowered.

In a further embodiment, the formation of the transparent layer stack (claim 2) comprises: forming a silicon oxide layer and, subsequently, a silicon and nitrogen containing layer in the form of a silicon nitride layer. Thereby, well known materials can be used which comprise the required optical characteristics, such as the refractive index, extension coefficient, whereby the antireflective effect is achieved by setting the material characteristics and the layer thickness on the basis of well known deposition processes. Therein, silicon nitride provides a sufficient etch selectivity for typical passivation materials in order to avoid an undesirably large material removal of the silicon nitride layer upon etching for forming the optical window.

In a further embodiment, the formation of the transparent layer stack comprises: forming a silicon oxide layer and, subsequently a silicon and nitrogen containing layer in the form of a silicon oxynitride layer. By using a silicon oxynitride material, the optical characteristics can be set by varying the oxygen content in the silicon nitride material in an efficient way, wherein this is done on the basis of established recipes such that a good definition of the antireflective characteristics can be achieved.

In a further embodiment, the layer stack is formed with a silicon oxide layer and a polyimide layer (claim 4). Therein, other materials, for example silicon nitride, can be used in the passivation layer and the metallization stack of the component since the polyimide provides the required etch selectivity.

In a further embodiment, the transparent layer stack is formed with a silicon oxide layer and an indium/tin oxide layer. Therein, the layer stack serving as etch stop layer, has an electrical conductivity which can be used in an advantageous way for contacting or shielding purposes.

In a further embodiment (related to the method according to one of the claims 1 to 5) is is the formation of a transparent layer stack and the formation of a silicon oxide layer having a thickness of at least 10 nm is comprised (claim 6). Thereby, a well defined and known border surface between the semiconductor region which is typically build up out of silicon, and the layer stack can be provided wherein a thickness in the range of 2 nm to 20 nm results in a comparatively small total thickness of the layer stack. The etch stop characteristics can be set by means of the layer or the layers, respectively, formed on the oxide layer, and the optical characteristics can be obtained in cooperation with the oxide layer so that those characteristics can be set in a flexible way. A preferred sub-range in the larger total range of the thickness is essentially 10 nm.

In a further embodiment, the method comprises determination of a material removal of the transparent layer stack upon etching of the one or several metallization levels and the selection of an appropriate thickness of the transparent layer stack taking into account the material removal. Thereby, the optical characteristics of the layer stack can be set in a defined way without the material removal having a negative influence. The material removal in the layer of the ARC-layer stack, used as etch stop, can be evaluated efficiently on the basis of suitable measurements or also from the known etch characteristics of known materials, and, thereby, they can be taken into account upon deposition for setting the thickness and/or the refractive index so that the required anti-reflecting effect can also be achieved after etching.

In a further embodiment of the claim 1, 10 or 18 a metal silicide layer is produced on contact areas of the optical semiconductor component. In particular, the fabrication is made before forming the transparent layer stack. Contrary to many conventional processes, the ARC-layer is made after the fabrication of the semiconductor component itself which includes, in a variation, the formation of well conducting metal silicide areas, but is prior to further steps, for example the deposition of passivation materials, such that the required intactness of the semiconductor is conserved with well conducting contacts.

In a further embodiment, the silicon and nitrogen containing layer is deposited at a temperature of 500° C. or higher in the range between 700° C. and 800° C., in particular above 750° C. (claim 9, claim 16, claim 22), which is further on also called a “high temperature deposition” for silicon nitride and silicon oxynitride. The deposition of the silicon and nitride containing layer at moderately high temperatures results in a lower hydrogen content whereby a higher refractive index and, thereby, a smaller layer thickness is sufficient for the same optical thickness, where from better optical characteristics are resulting and the yield and reliability of the circuits is increased.

A vertical region/portion describes a layer which has a smaller thickness dimension than the total layer but which extends across the breadth of the latter (claim 16).

In a further aspect of the invention, a method for fabricating integrated circuits with antireflective semiconductor surfaces by means of the interference effect of an antireflection layer (claim 10) is provided which is produced in an optical window of the semiconductor surface. The method comprises the fabrication of differently doped regions in the semiconductor substrate, removing of remaining layers above the semiconductor substrate and deposition of an antireflection coating in the area of the optical window. Therein, the thickness of the antireflection coating is chosen such that the antireflection coating is used additionally as etch stop layer, as passivation layer and as protective layer in the further fabrication process and during operation of the integrated circuits.

Because of this arrangement, the same advantageous effects can be achieved as they have already been mentioned above.

In a further aspect, a method for the fabrication of integrated circuits having antireflective semiconductor surfaces by the interference action of a antireflective coating is provided (claim 18) produced in an optical window on the semiconductor surface. After finishing the processes for the fabrication of differently diffused regions of the semiconductor substrate and the removal of remaining layers on the surface, a layer system is deposited which acts passivating, in this method. Subsequently, the optical window is freed by etching while using the layer system as etch stop layer. The layer system is used as the antireflection coating, wherein the layer system remains in the optical window after etching. This use is also to be seen as being adapted or having the property to further use the layer or the thus implemented layer stack which have been used previously in the production for other purposes, or as being “left in the optical window for further use”.

Also here, the above described advantages are valid.

In an advantageous embodiment, the layer system is deposited as a combination of two layers selectable from the substances silicon oxide, silicon nitride, oxynitride, silicon oxynitride, polyimide and ITO, whereby a high degree of flexibility is ensured when setting the optical and other characteristics, for example the conductivity so on, and the etch stop characteristic.

In a further advantageous embodiment, the layer system is deposited as a combination of three or more layers selectable from substances silicon oxide, silicon nitride, oxy nitride, silicon oxy nitride, polyimide and ITO (indium/tin oxide). Thereby, the flexibility with the setting of the required characteristics can be further improved.

The description of the layer system on the semiconductor surface is a further aspect of the invention (claim 21). The layer stack has multiple usage in the production and the operation of the component. Several second layers can be deposited on the first SiO₂-layer (claim 22). Preferably, the SiO₂-layer has a thickness of 10 nm.

The invention is explained and completed by way of embodiments with reference to the drawings.

### BRIEF DESCRIPTION OF THE DRAWINGS

FIG. 1 shows, as an example, a section through a silicon-PIN photodiode 100 as a part of an integrated circuit (not shown) of a four-layer-metal-technology.

FIG. 2 shows a section through a silicon pin photodiode 100′, wherein the material removal of the ARC-layer upon etching of the optical window is shown.

FIG. 2a shows a magnification of FIG. 2 at the bottom of the optical window 18.

FIG. 3 shows a section through a silicon pin photodiode 100″, wherein the ARC-layer stack comprises more than two layers.

FIG. 3a shows a magnification of FIG. 3 from the layer stack 16B and the bottom of the optical window 18.

### DETAILED DESCRIPTION OF PREFERRED EMBODIMENTS

The invention will now be clearly described with reference to embodiments and to a related drawing. The drawings are actually self-explanatory. This will be further explained in the following.

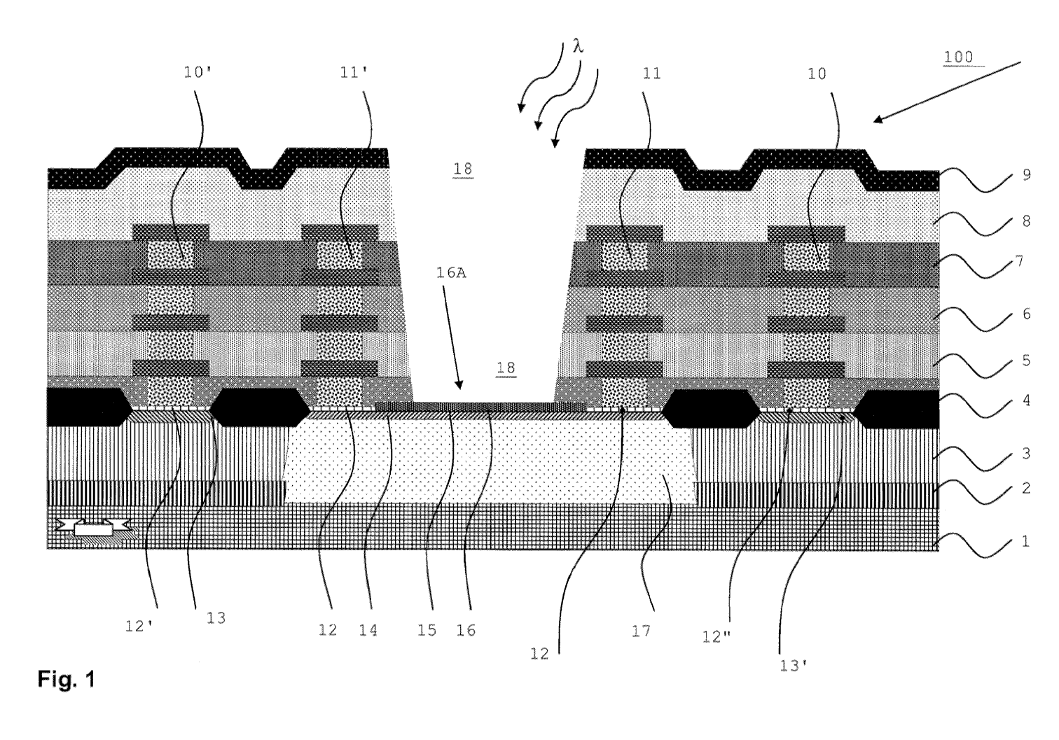

FIG. 1 shows schematically a section drawing of a silicon-PIN photodiode 100 which is to serve as an example of an optical component in an integrated circuit, without the invention, however, being delimited to a special optical component or a special construction.

The silicon-PIN photodiode 100 comprises a substrate 1, for example a highly doped p-substrate, a buried doped layer 2 which is formed on a p-well 3. A p-epitaxial layer 17 which is also called intrinsic region of the photo diode 100 because of its low doping, is provided next to the regions 2 and 3.

A field oxide 4 serves as a lateral isolation of the structures in the diode 100.

A metallization stack which is formed out of four metallization levels 5, 6, 7 and 8 in the example shown, is provided for the wiring of the single components of the total interpreted circuit, wherein a final passivation layer 9 covers the metallization stack.

In the metallization levels 5, 6, 7, 8, vertical connection structures are provided as anode 10, 10′ and cathode 11, 11′ for contacting the diode 100.

The electrodes 10, 10′ are connected through silicide regions 12′, 12″ with heavily doped contact regions or p+ regions 13, 13′, and the electrodes 11, 11′ are connected with the contact region or the n+ region 14 through one or several silicide regions 12.

If a rotational symmetry exists, the single depicted region 12′, 12″ or 13, 13′ are the same region as a ring-shaped structure.

Above the intrinsic region 17, a layer stack 16A is provided with layers 15 and 16 which are transparent for the specified wavelength range such that the bottom of an optical window 18 is formed by an area of the layers 15, 16 in order to couple radiation λ at least for the specified wavelength range into the intrinsic region 17.

In the embodiment shown, the layer stack 16A comprises two layers, whereby, in demonstrative embodiments, the layer 15 represents a silicon oxide layer having a thickness of about 10 nm, whereas the layer 16 is a silicon and nitrogen containing layer, for example a silicon nitride layer, a silicon oxynitride layer and the like. The thickness of the layer 15 can be as low as 2 nm and can be up to 20 nm.

In other embodiments, other substances, for example oxynitride, silicon oxynitride, polyimide and ITO can also used in combination with the above mentioned materials. At least the uppermost layer 16 has an etch selectivity with respect to the material of the adjoining metallization stack, at least with respect to the dielectric material of the level 5, such that the required etch stop characteristic is achieved upon forming the window 18.

In the cause of the process for the fabrication of the PIN-photodiode 100, the layer 16, for example as a silicon nitride layer, is deposited as a “silicide block layer” at an early point of time. Only a very thin (approximately 10 nm thick) oxide layer 15 is present there below in this embodiment.

If the silicon nitride layer 16 is now used because of its etch selectivity upon removal of the passivation layer 9 and upon etching of the metallization levels as etch stop, the surface of the semiconductor is not adversely effected since the sensible silicon surface is not exposed to an etch process at any time.

The layers 15 and 16 are, furthermore, produced at an early point of time, i.e. prior to the formation of the metallization level 5, already with a special layer thickness whereby they act, in combination, as simple antireflection layer system directly after back-etching the passivation. For this purpose, the layer thickness is dimensioned such that the optical thickness is achieved for the desired interference action and for the desired wavelength.

The oxide layer 15 can be varied in further examples in its thickness, down to 2 nm or up to 20 nm.

Processing steps for depositing of conventional antireflective layers can, thereby, be dispensed with. The extensive passivation etch step is simplified and stabilized by means of the defined etch stop of the ARC-layer 16 (for example silicon nitride). The etch process takes place in the optical window 18.

The quality of the layer 16 if it is provided as a silicon nitride material or a silicon oxy nitride material is another advantage of the method, since a high temperature silicon nitride can be deposited at an early point of time in the process, i.e. before the fabrication of the first metallization level 5. The temperature on deposition is above 700° C., in particular in the range of 750° C. to 800° C. The antireflection for blue light (at a wavelength of 405 nm) is remarkably improved. The remaining reflection losses are cut in half from 4% for a low temperature deposition to 2%. The nitride layer, furthermore, contains only very little hydrogen.

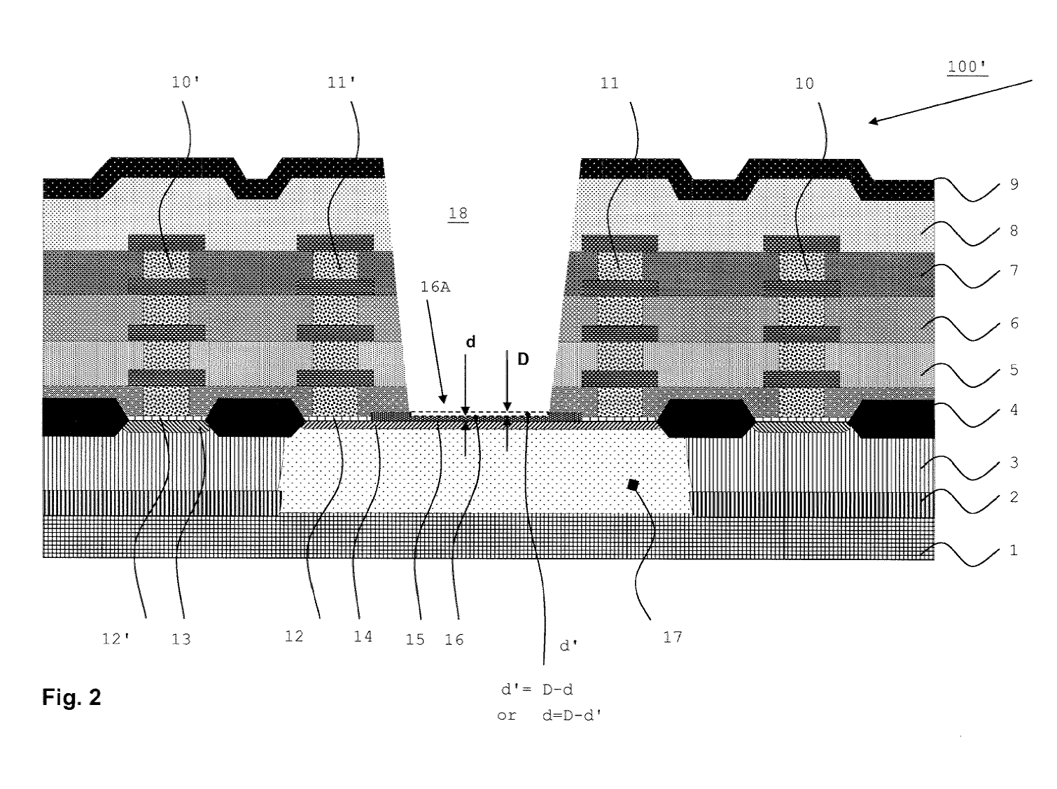

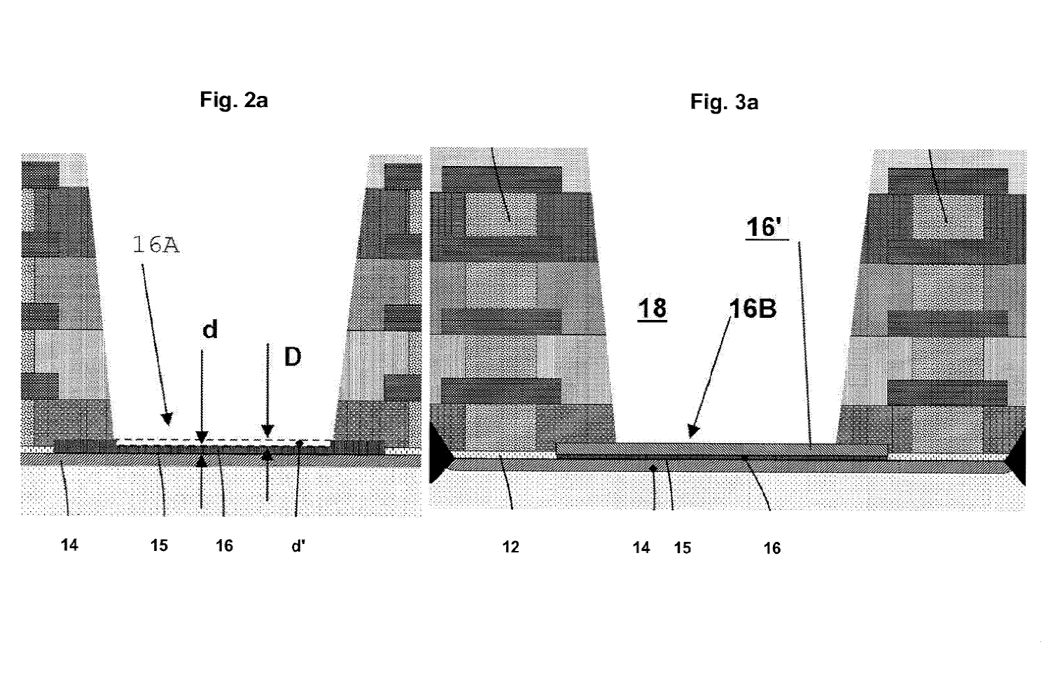

FIGS. 2 and 2a show schematically a reduction of the layer thickness of the layer 16 which can be brought about by the etch process, with a comparable, optically active component 100′. The correspondingly reduced layer thickness d is taken into account already upon deposition of the layer 16, if applicable in combination with the layer 15, in that a larger starting thickness D and/or the refractive index is/are set accordingly. By setting a higher refractive index, for a given thickness after the deposition, this thickness is, then, reduced by the material loss d′ to the thickness d required for the previously set refractive index.

In the same way, the starting thickness can be chosen larger for a given refractive index such that the required thickness d is, then, achieved after the etch process.

The enlargement according to FIG. 2a shows the at least two layers with a thinning by the measure d′ of the upper layer at the bottom of the optical window 18. A larger thickness D is removed by a vertical area which is described as material loss d′.

The elements 1 to 14 and 17 correspond in FIG. 2 those of FIG. 1. The bottom of the optical window 18 is to be seen more clearly in FIG. 2a, the ratio of thicknesses d, d′ and D with respect to each other and the placing of the layer 15 which it is hardly to be recognized in its real thickness/size but is located above the n+ region 14 and below the layer 16′.

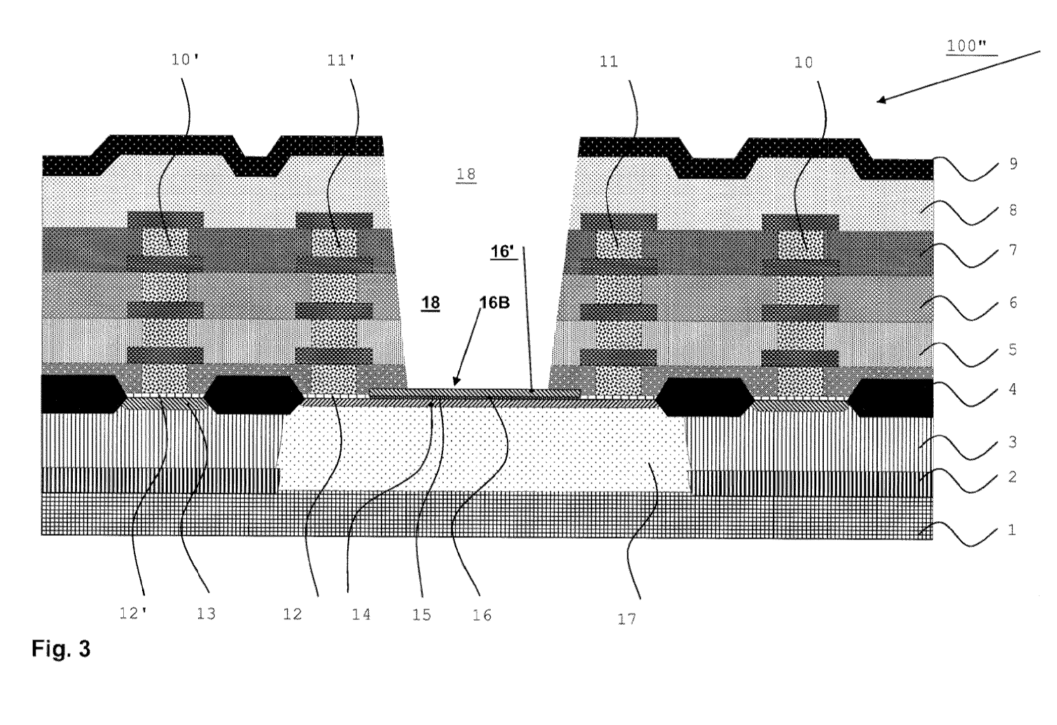

FIGS. 3 and 3a show a further comparable component 100″ with a layer stack 16B when it has three or more layers 15, 16, 16′, wherein an arbitrary combination of materials can be provided as long as the uppermost layer has the required etch stop property. In particular, the above mentioned materials can be used in an appropriate composition of the at least three layers 15, 16, 16′.

The magnification according to FIG. 3a nearly shows the at least three layers at the bottom of the window 18.

The elements 1 to 14 and 17 correspond to those of FIG. 1.

In some embodiments, the uppermost layer which can be arranged as an efficient etch stop layer 16′, is removed as necessary by a selective etch process which can run very gentle with respect to the layers located below so that the antireflection properties can be defined with high precision and essentially independently of the etch process.

In an illustrative embodiment, a method for selectively rendering the wafer surface antireflective in integrated circuits by means of the interference action of a layer system provided in an optical window of the semiconductor surface and consisting out of a very thin silicon oxide layer and a silicon nitride layer is provided.

The method distinguishes itself thereby that the “silicide block layer” out of silicon nitride which is usually produced in a comparatively early stage before the application of the naturalization levels on a thin silicon oxide layer as a high temperature layer having thickness values selected such that it protects the sensible semiconductor surface during the later procedure of the technology effectively against contaminations and defects and acts as an etch stop layer for the etch process of the optical window and also in combination with the thinner oxide layer has an anti reflection system.

### REFERENCE SIGNS

### The Same Reference Signs for the Same Elements in Different Figures

FIG. 1, FIG. 2, FIG. 2a, FIG. 3, FIG. 3a
1 highly doped p-substrate
2 buried p-layer
3 p-well
4 field oxide
5 first metallization level
6 second metallization level
7 third metallization level
8 fourth metallization level
9 final passivation layer
10 anode of the photo diode
11 cathode of the photo diode
12 silicide for improving the contacts
13 p+ region
14 n+ region
15 thin oxide (about 10 nm)
16 silicon nitride layer (silicide block layer)
17 p-epitaxial region (intrinsic region of the photo diode
16A layer stack
16B multilayer layer stack
16′ uppermost layer of the layer stack 16B having more than two layers
18 optical window
d′ material thickness loss upon etching
D starting thickness
d material thickness after the etching
100 PIN photo diode, 100′, 100″

1. Method for fabricating an optical semiconductor component having an optical window, wherein the method comprises the steps of:
forming a layer stack transparent within a defined wavelength arrange on a semiconductor area which is provided and adapted for coupling in a radiation (λ), wherein the transparent layer stack is produced with first optical characteristics which are adapted for a use as antireflection layer in connection with other optical characteristics of the semiconductor area;
forming one or several metallization levels above the transparent layer stack;
forming an optical window above the semiconductor area by etching the one or several metallization levels by using the transparent layer stack as etch stop layer.

2. Method according to claim 1, wherein the forming of the transparent layer stack comprises forming a silicon oxide layer and, subsequently, a silicon and nitrogen containing layer as a silicon nitride layer.

3. Method according to claim 1, wherein the forming of the transparent layer stack comprises forming a silicon oxide layer and, subsequently, a silicon and nitrogen containing layer in form of a silicon oxy nitride layer.

4. Method according to claim 1, wherein the forming of the transparent layer stack comprises forming a silicon oxide layer and, subsequently a polyimide layer.

5. Method according to claim 1, wherein the forming of the transparent layer stack comprises forming a silicon oxide layer and, subsequently, an indium/tin oxide layer.

6. Method according to claim 1, wherein the forming of the transparent layer stack comprises forming a silicon oxide layer having a thickness of between 2 nm to 20 nm, in particular, essentially 10 nm.

7. Method according to claim 1, wherein the forming of the transparent layer stack comprises
evaluating a material removal of the transparent layer stack upon etching of the one or the plurality of metallization levels, and
selecting an appropriate thickness of the transparent layer stack considering the material removal.

8. Method according to claim 1, further comprising:
forming a metal silicide layer of contact areas of the optical semiconductor component, in particular prior or after the forming of the transparent layer stack.

9. Method according to claim 2, wherein the silicon and nitrogen containing layer is deposited at a temperature of more than 500° C., in particular in the range between 750° C. to 800° C.

10. Method for fabricating of integrated circuits having antireflective semiconductor surfaces by means of an interference action of an antireflection layer produced in an optical window on the semiconductor surface, wherein the method comprises:
fabricating differently doped regions in a semiconductor substrate;
removing of remaining layers above the semiconductor substrate;
applying an antireflection layer in the area of the optical window, wherein a thickness of the antireflection layer is chosen such that the antireflection layer is adapted to be used, in a further fabrication process and upon operation of the integrated circuits, additionally as etch stop layer and as passivation layer and as protective layer.

11. Method according to claim 10, wherein the forming of the layer in the area of the optical window comprises a deposition of a silicon nitride layer.

12. Method according to claim 10, wherein the forming of the layer in the area of the optical window comprises forming an oxynitride layer.

13. Method according to claim 10, wherein the forming of the layer in the area of the optical window comprises forming a silicon oxynitride layer.

14. Method according to claim 10, wherein the forming of the layer in the area of the optical window comprises forming a polyimide layer.

15. Method according to claim 10, wherein the forming of the layer in the area of the optical window comprises forming a ITO-layer.

16. Method according to claim 11, wherein at least one vertical section is deposited as a partial layer of the layer at a temperature of at least 700° C.

17. Method according to claim 10, wherein the antireflection layer is formed before forming of the one or the plurality of metallization level(s).

18. Method for fabricating and/or for using an integrated circuit having an antireflective semiconductor surface by means of interference action of an anti reflection layer produced in an optical window on the semiconductor surface, wherein the method comprises:
after finalizing of processing for fabricating differently diffused regions of the semiconductor substrate and after removing of residual layers on the surface,
applying a layer system which effects passivation;
exposing/etching the optical window by using the layer system as etch stop layer;
using the layer system as antireflection layer whereby or wherefore the layer system remains in the optical window after the exposing/etching.

19. Method according to claim 18, wherein the layer system is applied as a combination of two layers selected of the substances silicon oxide, silicon nitride, oxy nitride, silicon oxy nitride, polyimide and ITO.

20. Method according to claim 18, wherein the layer system is applied as a combination of three or more layers selected from the substances silicon oxide, silicon nitride, oxy nitride, silicon oxy nitride, polyimide and ITO.

21. Semiconductor surface of an integrated circuit with an optical window at the bottom of which a layer system is located which consists out of a silicon oxide layer in a range of a thickness of between 2 nm to 20 nm and at least a second layer which are deposited after the fabrication of the component structures of the integrated circuit and prior to the application of the metallization levels,
(a) wherein the layers remain on the semiconductor surface at the bottom of the optical window;
(b) the at least one second layer is adapted to being used in connection with the silicon oxide layer as a layer system for selectively rendering the surface antireflective by means of the interference action in the optical window and for the protection of the sensible semiconductor surface against contaminations and defects and as etch stop layer upon exposing/etching the optical window, and wherein the appropriate thickness value for this purpose is set upon its deposition.

22. Semiconductor surface according to claim 21, wherein the at least one second layer is a silicon nitride layer deposited at a temperature range between 750° C. to 800° C.

23. Semiconductor surface according to claim 21, having a silicon oxide layer in a thickness/size of essentially 10 nm.
